(19) United States
(12) Patent Application Publication
(10) Pub. No.: US 2023/0048424 A1
(43) Pub. Date: Feb. 16, 2023

(54) SEMICONDUCTOR DEVICE AND METHOD FOR FABRICATING THE SAME

(71) Applicant: SK hynix Inc., Gyeonggi-do (KR)

(72) Inventor: Jun Sik KIM, Gyeonggi-do (KR)

(21) Appl. No.: 17/673,052

(22) Filed: Feb. 16, 2022

(30) Foreign Application Priority Data
Aug. 12, 2021 (KR) 10-2021-0106512

(51) Int. Cl. H01L 27/108; H01L 29/423; H01L 29/786; H01L 29/66

(52) U.S. Cl. CPC H01L 27/10805; H01L 27/10885; H01L 27/1085; H01L 29/42392; H01L 29/78618; H01L 29/78696; H01L 29/66742

(57) ABSTRACT

A semiconductor device includes: an active layer including a channel which is spaced apart from a substrate and extending in a direction parallel to a surface of the substrate; a gate dielectric layer formed over the active layer; a word line oriented laterally over the gate insulating layer to face the active layer, and including a low work function electrode and a high work function electrode which is parallel to the low work function electrode; and a dielectric capping layer disposed between the high work function electrode and the low work function electrode.

### CROSS-REFERENCE TO RELATED APPLICATIONS

The present application claims priority of Korean Patent Application No. 10-2021-0106512, filed on Aug. 12, 2021, which is incorporated herein by reference in its entirety.

### BACKGROUND

### 1. Field

Embodiments of the present invention relate to a semiconductor device, and more particularly, to a semiconductor device including memory cells of a three-dimensional structure and a method for fabricating the semiconductor device.

### 2. Description of the Related Art

Since the degree of integration of a two-dimensional (2D) memory device is mainly determined based on the area occupied by a unit memory cell, it is affected by a fine patterning technique. Ultra-high-price equipment is required for the fine patterning, but there is still limitation in increasing the degree of integration of a 2D memory device. To solve this problem, three-dimensional memory devices including memory cells that are arranged in three dimensions are proposed.

### SUMMARY

Embodiments of the present invention are directed to a semiconductor device including highly integrated memory cells, and a method for fabricating the semiconductor device.

In accordance with an embodiment of the present invention, a semiconductor device includes: an active layer including a channel which is spaced apart from a substrate and extending in a direction parallel to a surface of the substrate; a gate dielectric layer formed over the active layer; a word line oriented laterally over the gate dielectric layer to face the active layer, and including a low work function electrode and a high work function electrode which is parallel to the low work function electrode; and a dielectric capping layer disposed between the high work function electrode and the low work function electrode.

In accordance with another embodiment of the present invention, a method for fabricating a semiconductor device includes: forming an active layer which is vertically spaced apart from a substrate over an upper portion of the substrate; forming a gate dielectric layer over the active layer; forming a low work function electrode over the gate dielectric layer; forming a dielectric capping layer on one side of the low work function electrode; and forming a high work function electrode which is parallel to the low work function electrode over the dielectric capping layer.

In accordance with yet another embodiment of the present invention, a method for fabricating a semiconductor device includes: forming a stack body in which a first inter-layer dielectric layer, a first sacrificial layer, an active layer, a second sacrificial layer, and a second inter-layer dielectric layer are stacked in the mentioned order; forming a first opening passing through the stack body; forming recesses by recessing the first sacrificial layer and the second sacrificial layer through the first opening; thinning the active layer which is exposed by the recesses; forming a first gate dielectric layer over the thinned active layer; forming a low work function electrode partially filling the recesses over the first gate dielectric layer; forming a second gate dielectric layer by thinning a portion of the first gate dielectric layer which is exposed on one side of the low work function electrode; forming a dielectric capping layer over the second gate dielectric layer and one side of the low work function electrode; and forming a high work function electrode filling remaining portions of the recesses over the dielectric capping layer.

In accordance with still another embodiment of the present invention, a semiconductor device includes: an active layer including a channel which is spaced apart from a substrate and extends in a direction parallel to a surface of the substrate; a word line which is oriented laterally over the active layer to face the active layer and includes a low work function electrode and a high work function electrode that is parallel to the low work function electrode; a dielectric capping layer positioned between the high work function electrode and the low work function electrode; a first gate dielectric layer between the active layer and the low work function electrode; and a second gate dielectric layer which is positioned between the active layer and the high work function electrode and thinner than the first gate dielectric layer, wherein the dielectric capping layer extend to be positioned between the second gate dielectric layer and the high work function electrode.

In accordance with still another embodiment of the present invention, a semiconductor device includes: an active layer including a channel which is spaced apart from a substrate and extends in a direction parallel to a surface of the substrate; a word line which is oriented laterally over the active layer to face the active layer and includes a low work function electrode and a high work function electrode that is parallel to the low work function electrode; a single gate dielectric layer between the active layer and the low work function electrode; and a double gate dielectric layer positioned between the active layer and the high work function electrode, wherein a portion of the double gate dielectric layer extends to be positioned between the high work function and the active layer.

In accordance with still another embodiment of the present invention, a method for fabricating a semiconductor device comprising: forming a stack body including an active layer; forming a first opening passing vertically through the stack body; forming lateral recesses inside the stack body above and below the active layer to expose a part of the active layer; thinning the active layer which is exposed by the recesses; forming a low work function electrode partially filling the recesses; forming a high work function electrode filling remaining portions of the recesses, and forming a capping layer disposed between the low work function electrode and the high work function electrode

### BRIEF DESCRIPTION OF THE DRAWINGS

FIG. 1 is a schematic perspective view illustrating a memory cell in accordance with an embodiment of the present invention.

FIG. 2 is a cross-sectional view of the memory cell of FIG. 1.

FIG. 3 is a schematic perspective view illustrating a semiconductor memory device in accordance with an embodiment of the present invention.

FIG. 4 is a cross-sectional view of a vertical memory cell array (MCA_C) of FIG. 3.

FIG. 5 is a cross-sectional view of edge portions of double word lines.

FIG. 6, a modification of FIG. 5, is a cross-sectional view of a semiconductor memory device in accordance with another embodiment of the present invention.

FIG. 7 is a schematic perspective view illustrating a semiconductor memory device in accordance with another embodiment of the present invention.

FIGS. 8A to 8I are cross-sectional views illustrating a method for forming a double word line in accordance with an embodiment of the present invention.

FIGS. 9A to 9I are cross-sectional views illustrating a method for forming a bit line and a capacitor in accordance with an embodiment of the present invention.

FIGS. 10 and 11 are schematic perspective views illustrating memory cells in accordance with another embodiment of the present invention.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

According to the embodiment of the present invention described below, memory cell density may be increased and parasitic capacitance may be reduced by vertically stacking memory cells.

The embodiments of the present invention to be described below relate to a three-dimensional (3D) Dynamic Random Access Memory (DRAM) in which a word line may include a low work function electrode and a high work function electrode. The low work function electrode may be adjacent to a capacitor, and the high work function electrode may be adjacent to a bit line. The low work function electrode may include polysilicon, and the high work function electrode may include a metal-based material.

Due to the low work function of the low work function electrode, a low electric field may be formed between a word line and a capacitor, thereby improving the problem of leakage current.

The high work function of the high work function electrode may not only form a high threshold voltage, but also lower the height of the memory cell by forming a low electric field, which is advantageous in terms of integration degree.

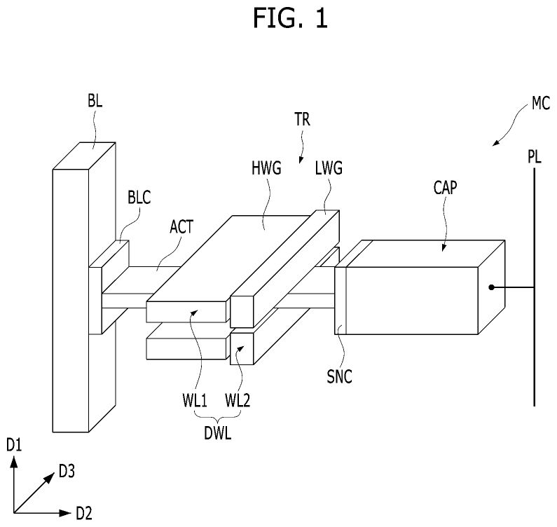

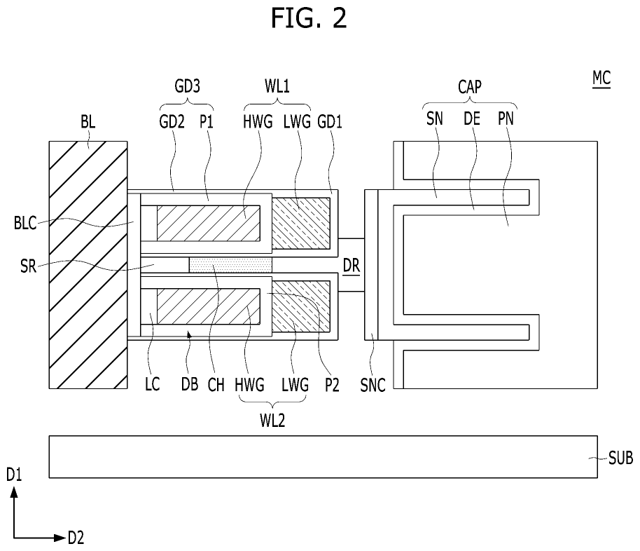

FIG. 1 is a schematic perspective view illustrating a memory cell in accordance with an embodiment of the present invention. FIG. 2 is a cross-sectional view of the memory cell shown in FIG. 1.

Referring to FIGS. 1 and 2, the memory cell MC may include a bit line BL, a transistor TR, and a capacitor CAP. The transistor TR may include an active layer ACT, gate dielectric layers GD1 and GD2, and a double word line DWL. The capacitor CAP may include a storage node SN, a dielectric layer DE, and a plate node PN.

The bit line BL may have a pillar shape extending in a first direction D1 which is perpendicular to the surface of a substrate SUB. The active layer ACT may have a bar shape extending in a second direction D2 which intersects with the first direction D1. The double word line DWL may have a line shape extending in a third direction D3 which intersects with the first direction D1 and the second direction D2. The plate node PN of the capacitor CAP may be coupled to a plate line PL.

The bit line BL may be vertically oriented in the first direction D1. The bit line BL may be referred to as a vertically oriented bit line or a pillar-type bit line. The bit line BL may include a conductive material. The bit line BL may include a silicon-based material, a metal-based material, or a combination thereof. The bit line BL may include polysilicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include a stack (TiN/W) of titanium nitride and tungsten.

The double word line DWL may extend along in the third direction D3, and the active layer ACT may extend in the second direction D2. The active layer ACT may be laterally arranged from the bit line BL. The double word line DWL may include a first word line WL1 and a second word line WL2. The first word line WL1 and the second word line WL2 may face each other with the active layer ACT interposed therebetween. Gate dielectric layers GD1 and GD2 may be formed over the upper and lower surfaces of the active layer ACT.

The active layer ACT may be spaced apart from the substrate SUB and extend in the second direction D2 which is parallel to the surface of the substrate SUB. The active layer ACT may include a semiconductor material. For example, the active layer ACT may include polysilicon, monocrystalline silicon, germanium, or silicon-germanium. The active layer ACT may include a channel CH, a first source/drain region SR between the channel CH and the bit line BL, and a second source/drain region DR between the channel CH and the capacitor CAP. According to another embodiment of the present invention, the active layer ACT may include an oxide semiconductor material. For example, the oxide semiconductor material may include indium gallium zinc oxide (IGZO). When the active layer ACT is of an oxide semiconductor material, the channel CH may be formed of an oxide semiconductor material, and the first and second source/drain regions SR and DR may be omitted.

The first source/drain region SR and the second source/drain region DR may be doped with an impurity of the same conductivity type. The first source/drain region SR and the second source/drain region DR may be doped with an N-type impurity or a P-type impurity. The first source/drain region SR and the second source/drain region DR may include at least one impurity selected among arsenic (As), phosphorus (P), boron (B), indium (In), and a combination thereof. A first side of the first source/drain region SR may contact the bit line BL, and a second side of the first source/drain region SR may contact the channel CH. A first side of the second source/drain region DR may be in contact with the storage node SN, and a second side of the second source/drain region DR may be in contact with the channel CH. The second side of the first source/drain region SR and the second side of the second source/drain region DR may partially overlap with the side of the first word line WL1 and the side of the second word line WL2, respectively.

The transistor TR may be a cell transistor and may have a double word line DWL. In the double word line DWL, the first word line WL1 and the second word line WL2 may have the same potential. For example, the first word line WL1 and the second word line WL2 may form a pair to be coupled to one memory cell MC. The same word line driving voltage may be applied to the first word line WL1 and the second word line WL2. As described above, the memory cell MC according to an embodiment of the present invention may have a double word line DWL in which two first word lines WL1 and two second word lines WL2 are disposed adjacent to one channel CH.

The active layer ACT may have a thickness which is smaller than the thicknesses of the first and second word lines WL1 and WL2. To be specific, the vertical thickness of the active layer ACT in the first direction D1 may be smaller than the vertical thickness of each of the first word line WL1 and the second word line WL2 in the first direction D1.

As described above, the thin active layer ACT may be referred to as a thin-body active layer. The thin active layer ACT may include a thin channel CH. The thin channel CH may be referred to as a ‘thin-body channel (CH)’. The thickness of the channel CH in the first direction D1 may be approximately 10 nm or less. According to another embodiment of the present invention, the channel CH may have the same thickness as the thicknesses of the first and second word lines WL1 and WL2.

The upper and lower surfaces of the active layer ACT may have a flat-surface. In other words, the upper surface and the lower surface of the active layer ACT may be parallel to each other in the second direction D2.

The gate dielectric layers GD1 and GD2 may include a first gate dielectric layer GD1 and a second gate dielectric layer GD2. The first gate dielectric layer GD1 may be thicker than the second gate dielectric layer GD2. The first gate dielectric layer GD1 and the second gate dielectric layer GD2 may be formed of the same material and may be formed to be integrated. The first and second gate dielectric layers GD1 and GD2 may include silicon oxide, silicon nitride, a metal oxide, a metal oxynitride, a metal silicate, a high-k material, and a ferroelectric material, an anti-ferroelectric material, or a combination thereof. The first and second gate dielectric layers GD1 and GD2 may include SiO₂, Si₃N₄, HfO₂, Al₂O₃, ZrO₂, AlON, HfON, HfSiO, HfSiON, HfZrO, or a combination thereof.

The first gate dielectric layer GD1 and the second gate dielectric layer GD2 may be positioned between the first word line WL1 and the active layer ACT. The first gate dielectric layer GD1 and the second gate dielectric layer GD2 may be positioned between the second word line WL2 and the active layer ACT. The first gate dielectric layers GD1 may be positioned between the second source/drain region DR and the first and second word lines WL1 and WL2. The second gate dielectric layers GD2 may be positioned between the channel CH and the first and second word lines WL1 and WL2. The second gate dielectric layers GD2 may extend to be positioned between the first source/drain region SR and the first and second word lines WL1 and WL2.

The double word line DWL may include a metal, a metal mixture, a metal alloy, or a semiconductor material. The double word line DWL may include titanium nitride, tungsten, polysilicon, or a combination thereof. For example, the double word line DWL may include a TiN/W stack in which titanium nitride and tungsten are sequentially stacked. The double word line DWL may include an N-type work function material or a P-type work function material. The N-type work function material may have a low work function of approximately 4.5 eV or lower, and the P-type work function material may have a high work function of approximately 4.5 eV or higher.

According to an embodiment of the present invention, the double word line DWL may be formed of a pair of two first word lines WL1 and two second word lines WL2 with the active layer ACT interposed therebetween. The double word line DWL may be coupled to one memory cell MC.

Each of the first and second word lines WL1 and WL2 may include a dual work function electrode. The dual work function electrode may be oriented laterally in the second direction D2 to face the active layer ACT over the first and second gate dielectric layers GD1 and GD2. The dual work function electrode may include a high work function electrode HWG and a low work function electrode LWG. The high work function electrode HWG and the low work function electrode LWG may be laterally adjacent to each other in the second direction D2. The low work function electrode LWG may be adjacent to the second source/drain region DR, and the high work function electrode HWG may be adjacent to the first source/drain region SR.

The low work function electrode LWG and the high work function electrode HWG may be formed of different work function materials. The high work function electrode HWG may have a higher work function than the low work function electrode LWG. The high work function electrode HWG may include a high work function material. The high work function electrode HWG may have a higher work function than a mid-gap work function of silicon. The low work function electrode LWG may include a low work function material. The low work function electrode LWG may have a lower work function than the mid-gap work function of silicon. For example, the high work function electrode HWG may have a work function of approximately 4.5 eV or higher, and the low work function electrode LWG may have a work function of approximately 4.5 eV or lower. The low work function electrode LWG may include doped polysilicon which is doped with an N-type impurity. The high work function electrode HWG may include a metal-based material. The high work function electrode HWG may include tungsten, titanium nitride, or a combination thereof. A conductive barrier layer may be further formed between the low work function electrode LWG and the high work function electrode HWG. Herein, the high work function electrode HWG may include tungsten, and the conductive barrier layer may include titanium nitride.

A width of the high work function electrode HWG in the second direction D2 may be longer than a width of the low work function electrode LWG in the second direction D2. A thickness of the low work function electrode LWG in the first direction D1 may be thicker than a thickness of the high work function electrode HWG in the first direction D1. The high work function electrode HWG may have a larger volume than the low work function electrode LWG, and accordingly, the first and second word lines WL1 and WL2 may have a low resistance.

Each of the high work function electrode HWG and the low work function electrode LWG may vertically overlap with the active layer ACT in the first direction D1. An overlapping area between the high work function electrode HWG and the active layer ACT may be greater than an overlapping area between the low work function electrode LWG and the active layer ACT. For example, the high work function electrode HWG and the active layer ACT may vertically overlap with each other in the first direction D1. The high work function electrode HWG and the first source/drain region SR may vertically overlap with each other in the first direction D1. The high work function electrode HWG and the channel CH may vertically overlap with each other in the first direction D1. The low work function electrode LWG and the active layer ACT may vertically overlap with each other in the first direction D1. The low work function electrode LWG and the second source/drain region DR may vertically overlap with each other in the first direction D1. The low work function electrode LWG and the channel CH may not vertically overlap with each other in the first direction D1. An overlapping area between the high work function electrode HWG and the channel CH may be greater than an overlapping area between the low work function electrode LWG and the second source/drain region DR. The low work function electrode LWG and the high work function electrode HWG may extend parallel to the third direction D3, and the low work function electrode LWG and the high work function electrode HWG may not directly contact each other.

A capping layer DB may be positioned between the low work function electrode LWG and the high work function electrode HWG. The capping layer DB may include a dielectric material. For example, the capping layer DB may include silicon oxide. The capping layer DB may cover the upper and lower surfaces of the high work function electrode HWG and may extend to be positioned between the low work function electrode LWG and the high work function electrode HWG. The low work function electrode LWG may contact the first gate dielectric layer GD1, and the capping layer DB may be positioned between the high work function electrode HWG and the second gate dielectric layer GD2. The capping layer DB may serve to block diffusion of impurities from the low work function electrode LWG. In other words, the capping layer DB may suppress loss of impurities in the low work function electrode LWG.

The capping layer DB may be conformally formed to include a first portion P1 and a second portion P2. The first portion P1 of the capping layer DB may cover the upper and lower surfaces of the high work function electrode HWG, and the second portion P2 of the capping layer DB may be positioned between the low work function electrode LWG and the high work function electrode HWG. The first portion P1 and the second portion P2 may have the same thickness.

According to another embodiment of the present invention, the capping layer DB may be formed non-conformally. In other words, the first portion P1 and second portion P2 may have different thicknesses. For example, the second portion P2 may be thinner than the first portion P1.

The first portion P1 of the capping layer DB may serve as a gate dielectric layer. In other words, a thick third gate dielectric layer GD3 including the second gate dielectric layer GD2 and the first portion P1 of the capping layer DB may be formed. The thick third gate dielectric layer GD3 may be formed between the high work function electrode HWG and the channel CH. The third gate dielectric layer GD3 may be thicker than the first gate dielectric layer GD1. The third gate dielectric layer GD3 may be referred to as a ‘channel-side gate dielectric layer’ contacting the channel CH. The third gate dielectric layer GD3 may reduce cell threshold voltage drop (CVT drop) and electric field degradation. The second portion P2 of the capping layer DB may prevent impurities from diffusing from the low work function electrode LWG.

Even though the dielectric capping layer DB is formed, the high work function electrode HWG and the low work function electrode LWG may be interconnected. From the perspective of a top view, one end of the high work function electrode HWG and one end of the low work function electrode LWG may be interconnected.

As described above, each of the first word line WL1 and the second word line WL2 may have a dual work function electrode structure including a low work function electrode LWG and a high work function electrode HWG. To be specific, the double word line DWL including the first word line WL1 and the second word line WL2 may have a pair of dual work function electrodes that extend in the third direction D3 crossing the channel CH with the channel CH interposed therebetween.

A bit line contact node BLC may be formed between the first source/drain region SR and the bit line BL. The bit line contact node BLC may have a height that fully covers the sides of the first source/drain region SR. The bit line contact node BLC may include polysilicon. For example, the bit line contact node BLC may include polysilicon doped with an impurity. Herein, the impurity may have the same conductivity type as the impurity of the first source/drain region SR.

A protection layer LC may be positioned between the bit line contact node BLC and the high work function electrode HWG. The protection layer LC may include a dielectric material, such as silicon nitride. The upper and lower surfaces of the protection layer LC may be covered by the capping layer DB. A combination of the capping layer DB and the protection layer LC may surround the upper surface, the lower surface, and both sides of the high work function electrode HWG.

The capacitor CAP may be disposed laterally in the second direction D2 from the transistor TR. The capacitor CAP may include a storage node SN which extends laterally from the active layer ACT in the second direction D2. The capacitor CAP may further include a dielectric layer DE and a plate node PN over the storage node SN. The storage node SN, the dielectric layer DE, and the plate node PN may be arranged laterally in the second direction D2. The storage node SN may have a laterally oriented cylinder shape. The dielectric layer DE may conformally cover the cylinder inner wall and the cylinder outer wall of the storage node SN. The plate node PN may have a shape extending toward the cylinder inner wall and the cylinder outer wall of the storage node SN over the dielectric layer DE. The plate node PN may be coupled to a plate line PL. The storage node SN may be electrically connected to the second source/drain region DR.

The storage node SN may have a three-dimensional structure, and the storage node SN of the three-dimensional structure may have a lateral three-dimensional structure which is oriented in the second direction D2. As an example of the three-dimensional structure, the storage node SN may have a cylinder shape. According to another embodiment of the present invention, the storage node SN may have a pillar shape or a pylinder shape. The pylinder shape may refer to a structure in which a pillar shape and a cylinder shape are merged. The uppermost surface of the storage node SN may be positioned at the same level as the upper surface of the first word line WL1. The lowermost surface of the storage node SN may be positioned at the same level as the bottom surface of the second word line WL2.

The storage node SN and the plate node PN may include a metal, a noble metal, a metal nitride, a conductive metal oxide, a conductive noble metal oxide, a metal carbide, a metal silicide, or a combination thereof. For example, the storage node SN and the plate node PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack or a tungsten nitride/tungsten (WN/W) stack. The plate node PN may include a combination of a metal-based material and a silicon-based material. For example, the plate node PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inside of the cylinder of the storage node SN, and titanium nitride (TiN) may serve as the plate node PN of the capacitor CAP. Tungsten nitride may be a low-resistance material.

The dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9, and the dielectric layer DE may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of a zirconium (Zr)-based oxide. The dielectric layer DE may have a stack structure including zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, the band gap energy of aluminum oxide (Al₂O₃) may be greater than those of zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-band gap material having a greater band gap than that of the high-k material. The dielectric layer DE may include silicon oxide (SiO₂) as a high bandgap material other than aluminum oxide (Al₂O₃). Since the dielectric layer DE includes a high band gap material, leakage current may be suppressed. The high band gap material may be thinner than the high-k material. According to another embodiment of the present invention, the dielectric layer DE may include a laminated structure in which a high-k material and a high-band gap material are alternately stacked. For example, the dielectric layer DE may include ZAZA (ZrO₂/Al₂O₃/ZrO₂/Al₂O₃), ZAZAZ (ZrO₂/Al₂O₃/ZrO₂/Al₂O₃/ZrO₂), HAHA (HfO₂/Al₂O₃/HfO₂/Al₂O₃) or HAHAH (HfO₂/Al₂O₃/HfO₂/Al₂O₃/HfO₂). In the laminated structure described above, aluminum oxide (Al₂O₃) may be thinner than zirconium oxide and hafnium oxide.

According to another embodiment of the present invention, the dielectric layer DE may include a stack structure, a laminated structure, or a mixed structure including zirconium oxide, hafnium oxide, and aluminum oxide.

According to another embodiment of the present invention, the dielectric layer DE may include a ferroelectric material or an antiferroelectric material.

According to another embodiment of the present invention, an interface control layer for improving leakage current may be further formed between the storage node SN and the dielectric layer DE. The interface control layer may include titanium oxide (TiO₂). The interface control layer may also be formed between the plate node PN and the dielectric layer DE.

The capacitor CAP may include a MIM (metal-insulator-metal) capacitor wherein the storage node SN and the plate node PN may include a metal-based material.

The capacitor CAP may be formed of other data storage materials. For example, the data storage material may be a phase-change material, a magnetic tunnel junction (MTJ), or a variable resistance material.

A storage contact node SNC may be formed between the second source/drain region DR and the storage node SN. The storage contact node SNC may have a height that fully covers the first side of the second source/drain region DR. The storage contact node SNC may include polysilicon. For example, the storage contact node SNC may include polysilicon which is doped with an impurity. Herein, the impurity may have the same conductivity type as the impurity of the second source/drain regions DR.

As described above, the memory cell MC may include a double word line DWL having a pair of dual work function electrodes. Each first word line WL1 and each second word line WL2 of the double word line DWL may include a low work function electrode LWG and a high work function electrode HWG. The low work function electrode LWG may be adjacent to the capacitor CAP, and the high work function electrode HWG may be adjacent to the bit line BL. Due to the low work function of the low work function electrode LWG, a low electric field may be formed between the double word line DWL and the capacitor CAP, thereby improving leakage current. Due to the high work function of the high work function electrode HWG, a high threshold voltage of the transistor TR may be formed, and the height of the memory cell MC may be lowered by forming a low electric field, which is advantageous in terms of integration degree.

In a Comparative Example 1 in which the first and second word lines WL1 and WL2 are formed of a metal-based material alone, a high electric field may be formed between the first and second word lines WL1 and WL2 and the capacitor CAP due to the high work function of the metal-based material, which deteriorates the leakage current of the memory cell. The deterioration of the leakage current due to the high electric field becomes worse, when the channel CH is thinner.

In a Comparative Example 2 in which the first and second word lines WL1 and WL2 are formed of a low work function material alone, the threshold voltage of the transistor may decrease due to the low work function, thereby generating leakage current.

In a Comparative Example 3 in which the capping layer DB is omitted between the low work function electrode LWG and the high work function electrode HWG, impurity loss occurs in the low work function electrode LWG, reducing the dual work function electrode effect.

In a Comparative Example 4 in which a conductive capping layer is positioned between the low work function electrode LWG and the high work function electrode HWG, since the thickness of the gate dielectric layer in contact with the channel CH cannot be increased, the cell threshold voltage may drop and the electric field may be degraded.

According to an embodiment of the present invention, since each of the first word lines WL1 and the second word lines WL2 of the double word line DWL has a dual work function electrode, the leakage current may be improved, thus securing refresh characteristics of the memory cell MC. This makes it possible to reduce power consumption.

According to an embodiment of the present invention, since each of the first word lines WL1 and the second word lines WL2 of the double word line DWL has a dual work function electrode, it may be relatively advantageous for increasing the electric field even though the thickness of the channel CH decreases for high integration. Therefore, a high number of stacking stages may be realized.

According to an embodiment of the present invention, since the thickness of the third gate dielectric layer GD3 contacting the channel CH is greater than the thickness of the first gate dielectric layer GD1, it is possible to reduce cell threshold voltage drop and electric field degradation.

According to an embodiment of the present invention, when the capping layer DB is formed, the effect of the dual work function electrode using a flat-band shift may be increased to reduce the gate-induced drain leakage (GIDL) which may be caused by the improvement of the electric field, and the operation current (TOP) may be increased.

As a result, the dielectric capping layer DB may increase the thickness of the gate dielectric layer in contact with the channel CH while increasing the dual work function electrode effect.

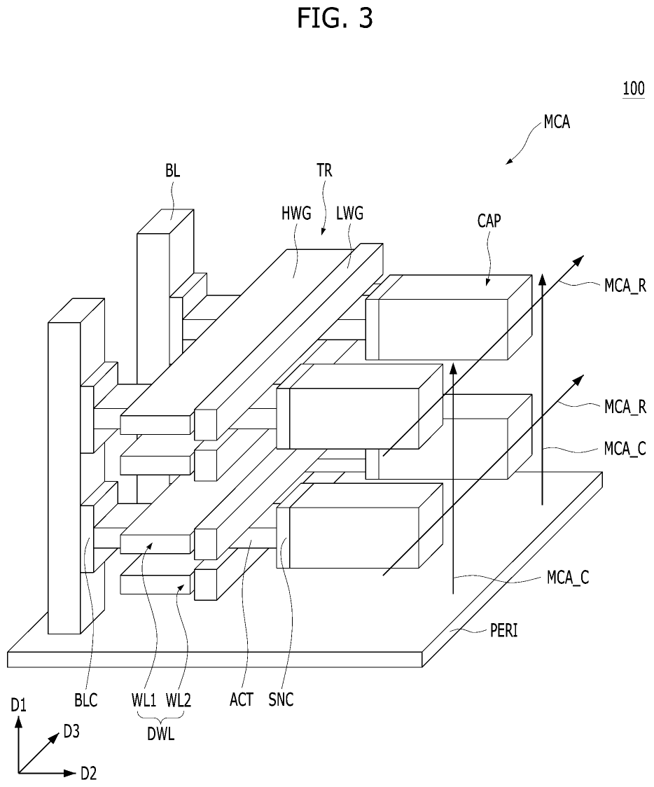

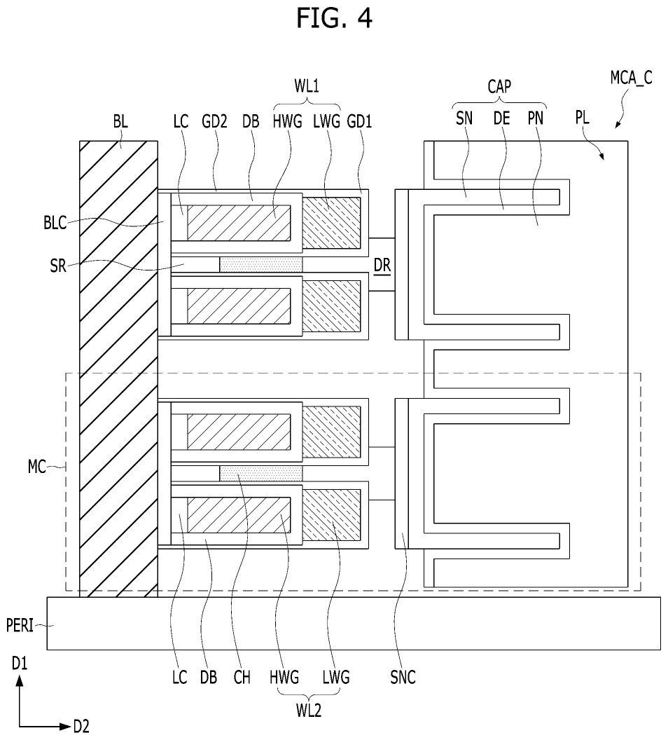

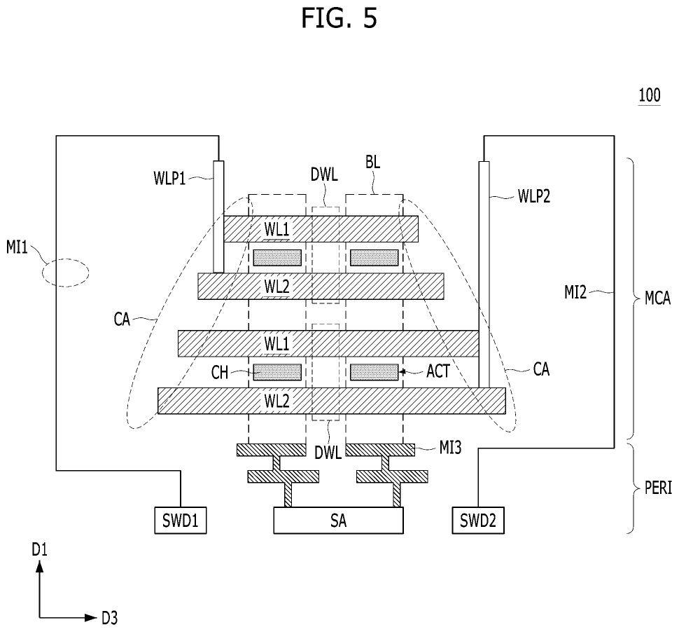

FIG. 3 is a schematic perspective view illustrating a semiconductor memory device in accordance with an embodiment of the present invention. FIG. 4 is a cross-sectional view of a vertical memory cell array (MCA_C) of FIG. 3. FIG. 5 is a cross-sectional view of edge portions of double word lines.

Referring to FIGS. 3 to 5, the semiconductor memory device 100 may include a memory cell array MCA. A plurality of memory cells MC shown in FIG. 1 may be arranged in the first to third directions D1, D2, and D3 to form a multi-layer memory cell array MCA. The memory cell array MCA may include a three-dimensional array of memory cells MC, and the three-dimensional memory cell array may include a vertical memory cell array MCA_C and a lateral memory cell array MCA_R. The vertical memory cell array MCA_C may refer to an array of memory cells MC that are vertically arranged in the first direction D1. The lateral memory cell array MCA_R may refer to an array of memory cells MC that are arranged laterally in the third direction D3. The vertical memory cell array MCA_C may be referred to as a column array of memory cells MC, and the lateral memory cell array MCA_R may be referred to as a row array of memory cells MC. The bit line BL may be vertically oriented to be coupled to the vertical memory cell array MCA_C, and the double word line DWL may be oriented laterally to be coupled to the lateral memory cell array MCA_R. The bit line BL coupled to the vertical memory cell array MCA_C may be referred to as a common bit line, and the vertical memory cell arrays MCA_C that are adjacent to each other in the third direction D3 may be coupled to different common bit lines. The double word line DWL coupled to the lateral memory cell array MCA_R may be referred to as a common double word line Common DWL, and the lateral memory cell arrays MCA_R that are adjacent to each other in the first direction D1 may be coupled to different common double word lines.

The memory cell array MCA may include a plurality of memory cells MC, and each of the memory cells MC may include a vertically oriented bit line BL, a laterally oriented active layer ACT, a double word line DWL, and a laterally oriented capacitor CAP. FIG. 3 illustrates a three-dimensional memory cell array including four memory cells MC.

One bit line BL may contact the active layers ACT that are adjacent to each other in the first direction D1. The active layers ACT that are adjacent to each other in the third direction D3 may share a double word line DWL. The number of capacitors CAP may correspond to the number of active layers ACT and each capacitor may be coupled to a corresponding one of the active layers ACT. The capacitors CAP may share one plate line PL. Each of the active layers ACT may be thinner than the first and second word lines WL1 and WL2 of the double word line DWL.

In the memory cell array MCA, two double word lines DWL may be vertically stacked in the first direction D1. Each of the double word lines DWL may include a pair of a first word line WL1 and a second word line WL2. A plurality of active layers ACT may be arranged laterally to be spaced apart from each other in the third direction D3. Each active layer ACT may extend in the second direction D2 and may pass through between the first word line WL1 and the second word line WL2.

Each of the active layers ACT may include a channel CH, a first source/drain region SR, and a second source/drain region DR. The channel CH may be positioned between the first word line WL1 and the second word line WL2. Each first source/drain regions SR may be coupled to each bit line contact node BLC, and the bit line contact nodes BLC may be coupled to one bit line BL. Each second source/drain regions DR may be coupled to each storage contact node SNC, and the storage contact nodes SNC may be coupled to a storage node SN.

Each of the first word line WL1 and the second word line WL2 of the double word line DWL may include a low work function electrode LWG and a high work function electrode HWG. The low work function electrodes LWG may be adjacent to the capacitor CAP, and the high work function electrodes HWG may be adjacent to the bit line BL.

Referring back to FIG. 5, the edge portions on both sides of each double word line DWL may have a step shape, and the step shape may define contact portions CA. Each of the first word lines WL1 and the second word lines WL2 may include edge portions on both sides, that is, the contact portions CA. Each of the contact portions CA may have a step shape.

A plurality of word line pads WLP1 and WLP2 may be respectively coupled to the contact portions CA. A first word line pad WLP1 may be coupled to an upper-level double word line DWL, e.g., the contact portions CA of the first word line WL1 and the second word line WL2 of an upper level. A second word line pad WLP2 may be coupled to a lower-level double word line DWL, e.g., the contact portions CA of the first word line WL1 and the second word lines WL2 of a lower level. The upper-level first word line WL1 and the upper-level second word line WL2 may be interconnected by the first word line pad WLP1. The lower-level first word line WL1 and the lower-level second word line WL2 may be interconnected by the second word line pad WLP2. Each of the first word line WL1 and the second word line WL2 may include a high work function electrode HWG and a low work function electrode LWG, and a one-side end of the high work function electrode HWG in a contact portion CA may be interconnected to a one-side end of the low work function electrode LWG.

The semiconductor memory device 100 may further include a substrate PERI, and the substrate PERI may include a peripheral circuit portion. Hereinafter, the substrate PERI will be simply referred to as a peripheral circuit portion PERI. The bit line BL of the memory cell array MCA may be oriented in the first direction D1 perpendicular to the upper surface of the peripheral circuit portion PERI, and the double word line DWL may be oriented in the third direction D3 parallel to the upper surface of the peripheral circuit portion PERI.

The peripheral circuit portion PERI may be positioned at a lower level than the memory cell array MCA. This may be referred to as a COP (cell over PERI) structure. The peripheral circuit portion PERI may include at least one control circuit for driving the memory cell array MCA. At least one control circuit of the peripheral circuit portion PERI may include an N-channel transistor, a P-channel transistor, a CMOS circuit, or a combination thereof. At least one control circuit of the peripheral circuit portion PERI may include an address decoder circuit, a read circuit, a write circuit, and the like. At least one control circuit of the peripheral circuit portion PERI may include a planar channel transistor, a recess channel transistor, a buried gate transistor, a fin channel transistor (FinFET) and the like.

For example, the peripheral circuit portion PERI may include sub-word line drivers SWD1 and SWD2 and a sense amplifier SA. The upper-level double word line DWL may be coupled to the first sub-word line driver SWD1 through the first word line pads WLP1 and the first metal interconnection MI1. The lower-level double word line DWL may be coupled to the second sub-word line driver SWD2 through the second word line pads WLP2 and the second metal lines MI2. The bit lines BL may be coupled to the sense amplifier SA through the third metal interconnection MI3. The third metal interconnection MI3 may have a multi-level metal structure including a plurality of vias and a plurality of metal lines.

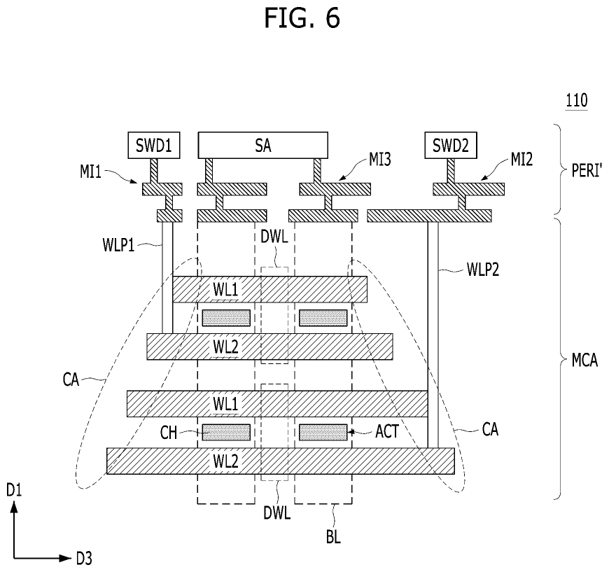

FIG. 6 is a cross-sectional view illustrating a semiconductor memory device in accordance with another embodiment of the present invention. FIG. 6 illustrates a semiconductor memory device 110 having a POC (PERI over Cell) structure. Detailed description of the constituent elements shown in FIG. 6 also appearing in FIG. 5 will be omitted.

Referring to FIG. 6, the semiconductor memory device 110 may include a memory cell array MCA and a peripheral circuit portion PERI′. The peripheral circuit portion PERI′ may be positioned at a higher level than the memory cell array MCA. This may be referred to as a POC (PERI over Cell) structure.

The peripheral circuit portion PERI′ may include sub-word line drivers SWD1 and SWD2 and a sense amplifier SA. The upper-level double word line DWL may be coupled to the first sub-word line driver SWD1 through the first word line pads WLP1 and the first metal interconnection MI1. The lower-level double word line DWL may be coupled to the second sub-word line driver SWD2 through the second word line pads WLP2 and the second metal interconnection MI2. The bit lines BL may be coupled to the sense amplifier SA through the third metal interconnection MI3. The third metal interconnection MI3 may have a multi-level metal structure including a plurality of vias and a plurality of metal lines.

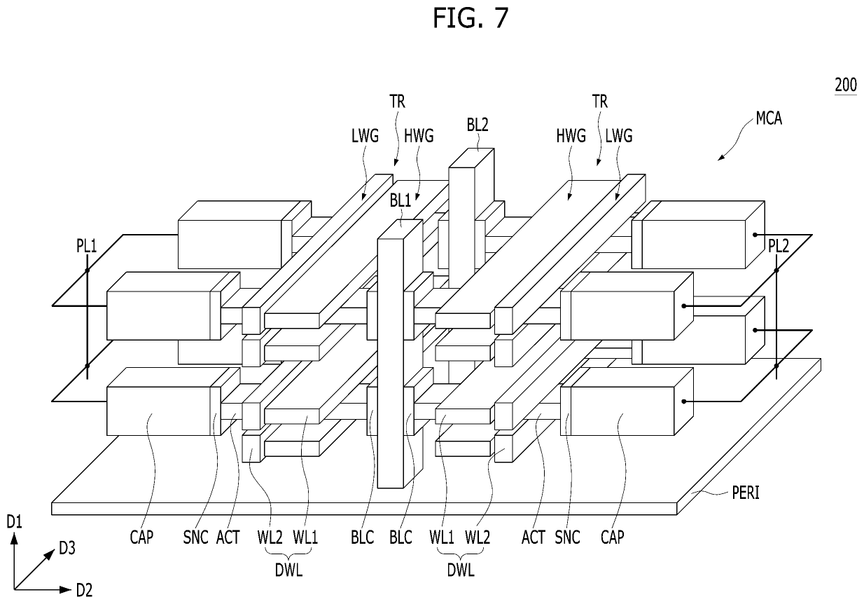

FIG. 7 is a schematic perspective view illustrating a semiconductor memory device in accordance with another embodiment of the present invention. In FIG. 7, detailed description on the constituent elements also appearing in FIGS. 1 to 6 will be omitted.

Referring to FIG. 7, the semiconductor memory device 200 may include a peripheral circuit portion PERI and a memory cell array MCA disposed over the peripheral circuit portion PERI. The memory cell array MCA may include a plurality of memory cells. Referring to the memory cell array MCA of FIG. 3, the memory cell array MCA may include a column array of memory cells and a row array of memory cells. Each of the memory cells may include a transistor TR and a capacitor CAP, and each of the transistors TR may include an active layer ACT and a double word line DWL. The double word line DWL may include a low work function electrode LWG and a high work function electrode HWG that are laterally adjacent to each other in the second direction D2. Each of the capacitors CAP may be coupled to a corresponding one of the active layers ACT through a corresponding storage contact node SNC. Each of the bit lines BL1 and BL2 may be coupled to corresponding ones of the active layers ACT through a corresponding bit line contact node BLC.

The column array of memory cells may include a mirror-type structure sharing bit lines BL1 and BL2.

For example, a column array including memory cells that are arranged laterally in the second direction D2 with the first bit line BL1 interposed therebetween may be arranged in a mirror-type structure in which the first bit line BL1 is shared while being coupled to different plate lines PL1 and PL2. A column array including memory cells that are arranged laterally in the second direction D2 with the second bit line BL2 interposed therebetween may be arranged in a mirror-type structure in which the second bit line BL2 is shared while being coupled to the different plate lines PL1 and PL2.

According to another embodiment of the present invention, the semiconductor memory device 200 may include a mirror-type structure sharing a plate line.

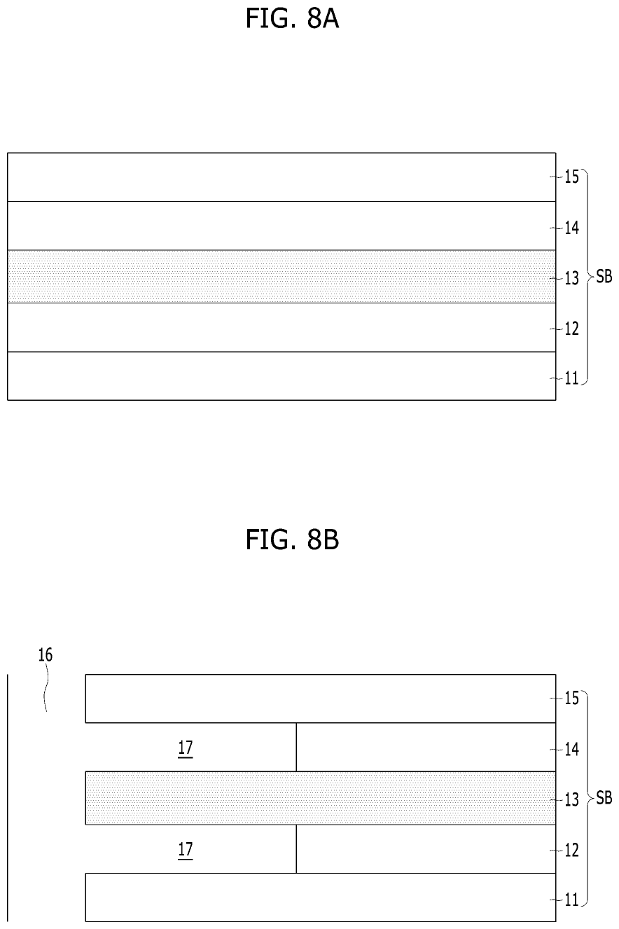

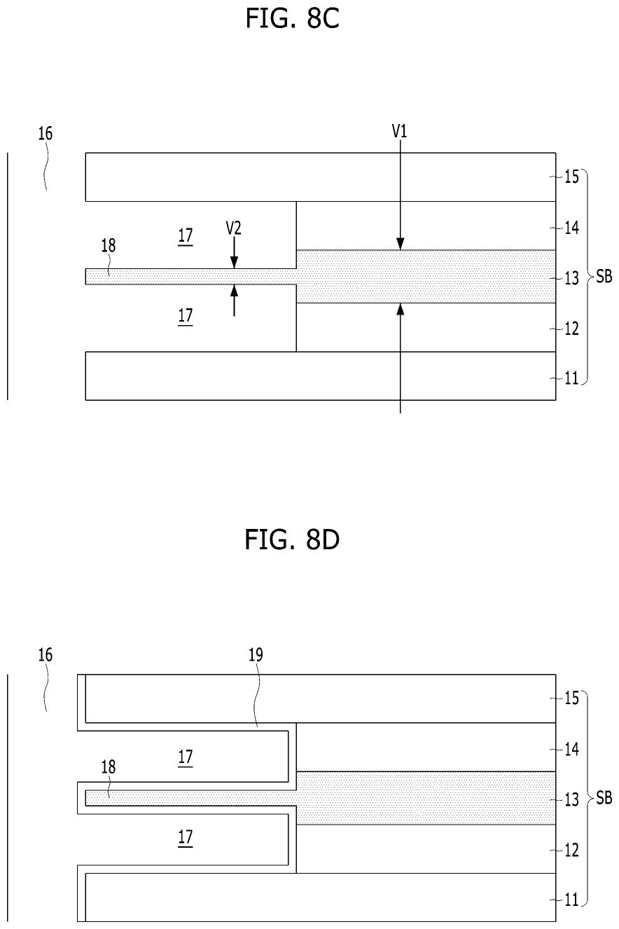

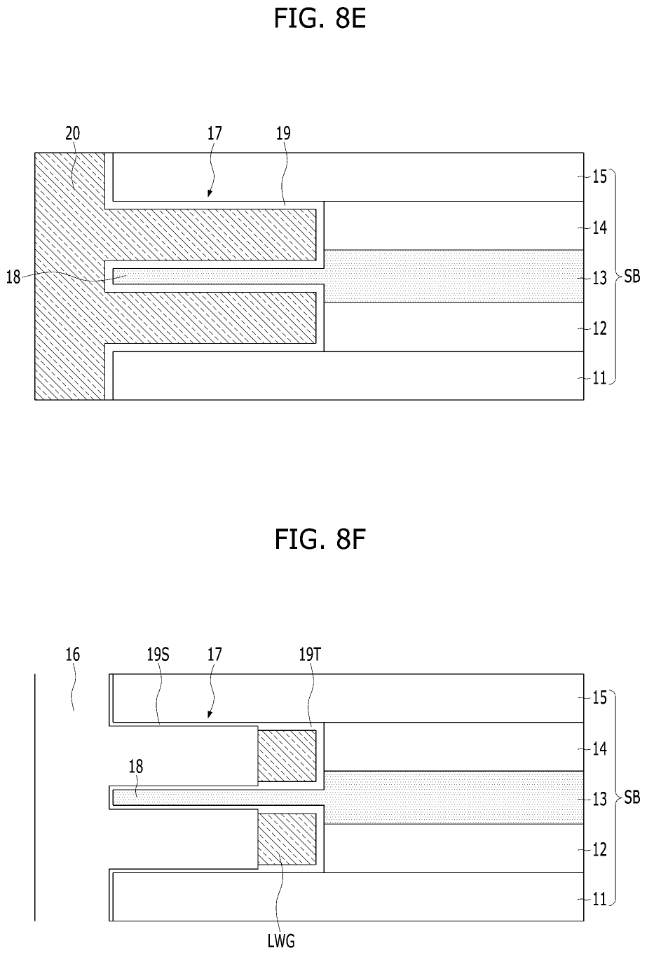

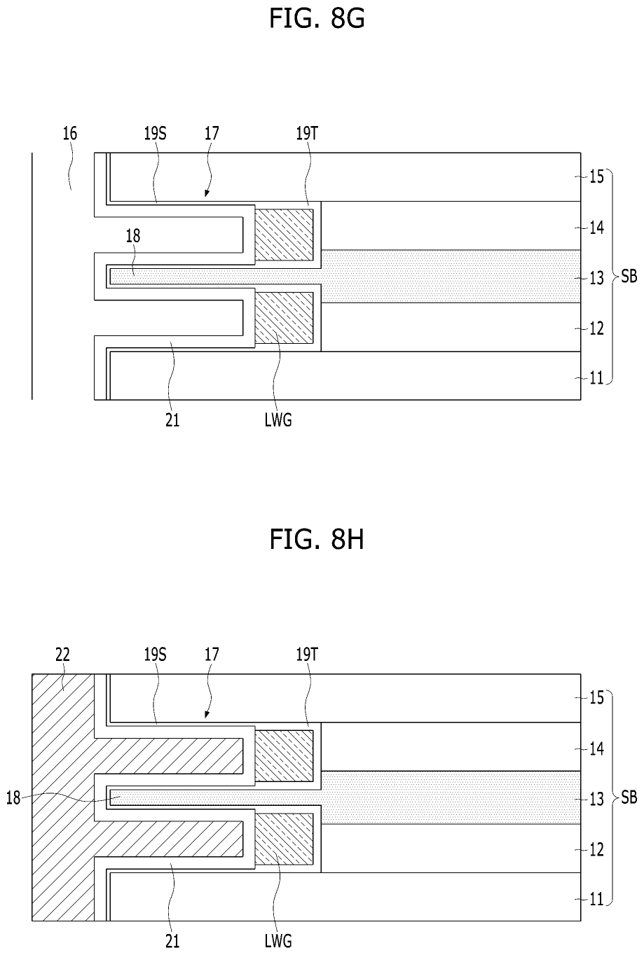

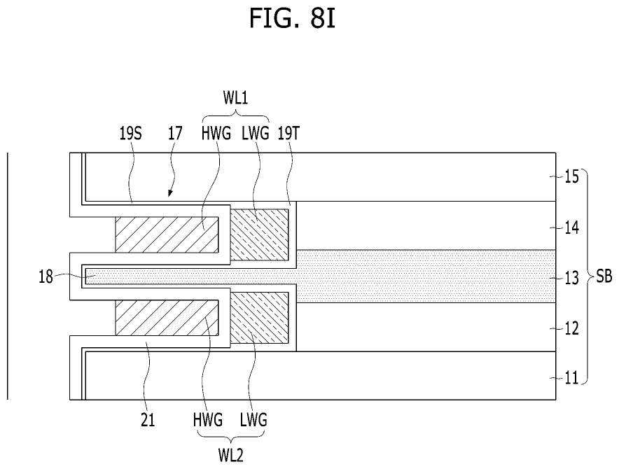

FIGS. 8A to 8I are cross-sectional views illustrating a method for forming a double word line in accordance with an embodiment of the present invention.

Referring to FIG. 8A, a stack body SB may be formed. The stack body SB may include inter-layer dielectric layers 11 and 15, sacrificial layers 12 and 14, and an active layer 13. The active layer 13 may be positioned between the first inter-layer dielectric layer 11 and the second inter-layer dielectric layer 15. A first sacrificial layer 12 may be positioned between the first inter-layer dielectric layer 11 and the active layer 13, and a second sacrificial layer 14 may be positioned between the second inter-layer dielectric layer 15 and the active layer 13. The first and second inter-layer dielectric layers 11 and 15 may include silicon oxide, and the first and second sacrificial layers 12 and 14 may include silicon nitride. The active layer 13 may include a semiconductor material or an oxide semiconductor material. The active layer 13 may include monocrystalline silicon, polysilicon, germanium, silicon-germanium, or IGZO.

Referring to FIG. 8B, a first opening 16 may be formed by etching a first portion of the stack body SB. The first opening 16 may extend vertically. The first opening 16 may pass through the stack body SB. A plurality of active layers 13 may be formed between the first and second sacrificial layers 12 and 14. For example, similar to the active layer ACT shown in FIG. 3, a plurality of active layers 13 may be arranged laterally on the same plane. For example, forming the active layers 13 may include: forming a stack body SB such that the first sacrificial layer 12 and the second sacrificial layer 14 are positioned between the first inter-layer dielectric layer 11 and the second inter-layer dielectric layer 15 and a planar semiconductor layer is positioned between the first sacrificial layer 12 and the second sacrificial layer 14; forming a plurality of isolation holes (not shown) by etching the stack body SB; and forming a plurality of line-type semiconductor layers that are arranged laterally between the first sacrificial layer 12 and the second sacrificial layer 14 by recess-etching the planar semiconductor layer through the isolation holes.

Subsequently, the first and second sacrificial layers 12 and 14 may be selectively etched through the first opening 16 to form recesses 17. A portion of the active layer 13 may be exposed by the recesses 17.

Referring to FIG. 8C, exposed portions of the active layer 13 may be recessed. Accordingly, the exposed upper and lower surfaces of the active layer 13 may be thinned to form a thin-body 18. For example, the residual active layer 13 may have a first thickness V1, and the thin-body 18 may have a second thickness V2. The second thickness V2 of the thin-body 18 may be thinner than the first thickness V1 of the residual active layer 13. The process of recessing the exposed portions of the active layer 13 may be referred to as a thinning process.

Referring to FIG. 8D, a gate dielectric layer 19 may be formed over the exposed portion of the thin-body 18. The gate dielectric layer 19 may also be formed over the exposed portion of the remaining active layer 13, the exposed portion of the first and second sacrificial layers 12 and 14, and the exposed portions of the first and second inter-layer dielectric layers 11 and 15. The exposed portions of the thin-body 18, of the remaining active layer 13, of the first and second sacrificial layers 12 and 14, and of the first and second inter-layer dielectric layers 11 and 15 are those portions which are exposed to the opening 16 or to the recesses 17. The gate dielectric layer 19 may be formed of silicon oxide, silicon nitride, a metal oxide, a metal oxynitride, a metal silicate, a high-k material, a ferroelectric material, an anti-ferroelectric material, or a combination thereof. The gate dielectric layer 19 may include SiO₂, Si₃N₄, HfO₂, Al₂O₃, ZrO₂, AlON, HfON, HfSiO, HfSiON, HfZrO, or a combination thereof.

Referring to FIG. 8E, a low work function material 20 may be formed over the gate dielectric layer 19. The low work function material 20 may fill the first opening 16 and the recesses 17 over the gate dielectric layer 19. For example, the low work function material 20 may include doped polysilicon which is doped with an N-type impurity.

Referring to FIG. 8F, a low work function electrode LWG may be formed in the recesses 17. In order to form the low work function electrode LWG, a selective etching process of the low work function material 20 may be performed. The selective etching of the low work function material 20 may include dry etching or wet etching. The selective etching of the low work function material 20 may be performed by blanket etching without a mask. The selective etching process of the low work function material 20 may include an etch-back process.

For example, when the low work function material 20 includes doped polysilicon, an etch-back process of the doped polysilicon may be performed to form the low work function electrode LWG.

Portions of the gate dielectric layer 19 may be lost while the low work function electrode LWG is formed as described above. Accordingly, the exposed portions of the gate dielectric layer 19 may be thinned to form the second gate dielectric layer 19S. For example, the gate dielectric layer 19 may remain as a first gate dielectric layer 19T which is thicker than the second gate dielectric layer 19S. A thick first gate dielectric layer 19T may be formed between the thin body 18 and the low work function electrode LWG.

Referring to FIG. 8G, a capping layer 21 may be formed over the second gate dielectric layer 19S and the low work function electrode LWG. The capping layer 21 may include a dielectric material. The capping layer 21 may include silicon oxide. The capping layer 21 may cover the surfaces of the recesses 17. The capping layer 21 may cover the exposed surfaces of the low work function electrode LWG. The capping layer 21 may block diffusion of the impurities from the low work function electrode LWG. For example, when the low work function electrode LWG is doped polysilicon, the capping layer 21 may block diffusion of impurities from the doped polysilicon.

Also, the capping layer 21 may reinforce the thickness of the second gate dielectric layer 19S which is lost during an etching process for forming the low work function electrode LWG. The capping layer 21 may be thicker than the second gate dielectric layer 19S. Although, in the embodiment shown in FIG. 8G, the capping layer 21 may be thicker than the first gate dielectric layer 19S, the invention is not limited in this way and in a variation of the described embodiment the capping layer 21 may be thinner than the first gate dielectric layer 19T. According to another embodiment of the present invention, the capping layer 21 and the second gate dielectric layer 19S may have the same thickness, and the capping layer 21 may be thinner than the first gate dielectric layer 19T. According to another embodiment of the present invention, the total thickness of the capping layer 21 and the second gate dielectric layer 19S may be the same as the thickness of the first gate dielectric layer 19T.

The capping layer 21 may be formed by deposition of silicon oxide, followed by rapid thermal treatment (RTA). The deposition of silicon oxide may be performed through the first opening 16.

According to another embodiment of the present invention, a capping layer 21 may be formed by an oxidation process such as RTO (Rapid Thermal Oxidation). For example, the capping layer 21 may be formed by selectively oxidizing the exposed surfaces of the low work function electrode LWG, and the oxidation process may also re-oxidize the exposed portions of the second gate dielectric layer 19S.

The capping layer 21 may have a conformal thickness. The capping layer 21 may have a non-conformal thickness. The conformal thickness may be the same as the thickness formed on the surface of the low work function electrode LWG and the thickness formed on the surface of the second gate dielectric layer 19S. The non-conformal thickness may be thicker than the thickness formed on the surface of the low work function electrode LWG and the thickness formed on the surface of the second gate dielectric layer 19S.

The first and second gate dielectric layers 19T and 19S and the capping layer 21 may be formed of the same material. For example, the first and second gate dielectric layers 19T and 19S and the capping layer 21 may be formed of silicon oxide. In another embodiment, the first and second gate dielectric layers 19T and 19S and the capping layer 21 may be formed of different materials. For example, the first and second gate dielectric layers 19T and 19S may be formed of a high-k material, a ferroelectric material, or an antiferroelectric material, and the capping layer 21 may be formed of silicon oxide.

Referring to FIG. 8H, a high work function material 22 filling the recesses 17 and the first opening 16 may be formed over the capping layer 21. The high work function material 22 may have a higher work function than the low work function electrode LWG and may have a lower resistance than the low work function electrode LWG. The high work function material 22 may include a metal-based material. For example, the high work function material 22 may include titanium nitride, tungsten, or a combination thereof. According to an embodiment of the present invention, the high work function material 22 may be formed by sequentially stacking titanium nitride and tungsten.

Referring to FIG. 8I, a high work function electrode HWG may be formed in each of the recesses 17. In order to form the high work function electrode HWG, the high work function material 22 may be selectively etched.

The high work function electrode HWG may be adjacent to one side of the low work function electrode LWG with the capping layer 21 interposed therebetween. The high work function electrode HWG may have a higher work function than the low work function electrode LWG. The high work function electrode HWG may include a metal-based material. For example, the high work function electrode HWG may include titanium nitride, tungsten, or a combination thereof, and the low work function electrode LWG may include doped polysilicon which is doped with an N-type impurity.

A thick first gate dielectric layer 19T may be formed between the thin body 18 and the low work function electrode LWG, and a thin second gate dielectric layer 19S may be formed between the thin body 18 and the high work function electrode HWG. A capping layer 21 may be positioned between the second gate dielectric layer 19S and the high work function electrode HWG. The capping layer 21 may be positioned between the high work function electrode HWG and the low work function electrode LWG. The capping layer 21 may block diffusion of impurities from the low work function electrode LWG toward the high work function electrode HWG.

A first word line WL1 and a second word line WL2 may be formed with the thin body 18 interposed therebetween. The first and second word lines WL1 and WL2 may correspond to the double word line DWL which appears in FIGS. 1 to 7. Each of the first and second word lines WL1 and WL2 may be a dual work function electrode which includes a low work function electrode LWG and a high work function electrode HWG.

According to the above-described embodiment, as the dielectric capping layer 21 is formed, impurity loss of the low work function electrode LWG may be suppressed, thereby increasing the dual gate effect using a flat-band shift. Accordingly, it is possible to reduce the gate-induced drain leakage (GIDL) that may be caused by the improvement of an electric field (e-field) and to increase the operation current. Also, as the dielectric capping layer 21 is formed, the thickness of the second gate dielectric layer 19S that is lost during the formation of the low work function electrode LWG may be reinforced. In other words, the capping layer 21 and the second gate dielectric layer 19S may serve as a gate dielectric layer having an increased thickness.

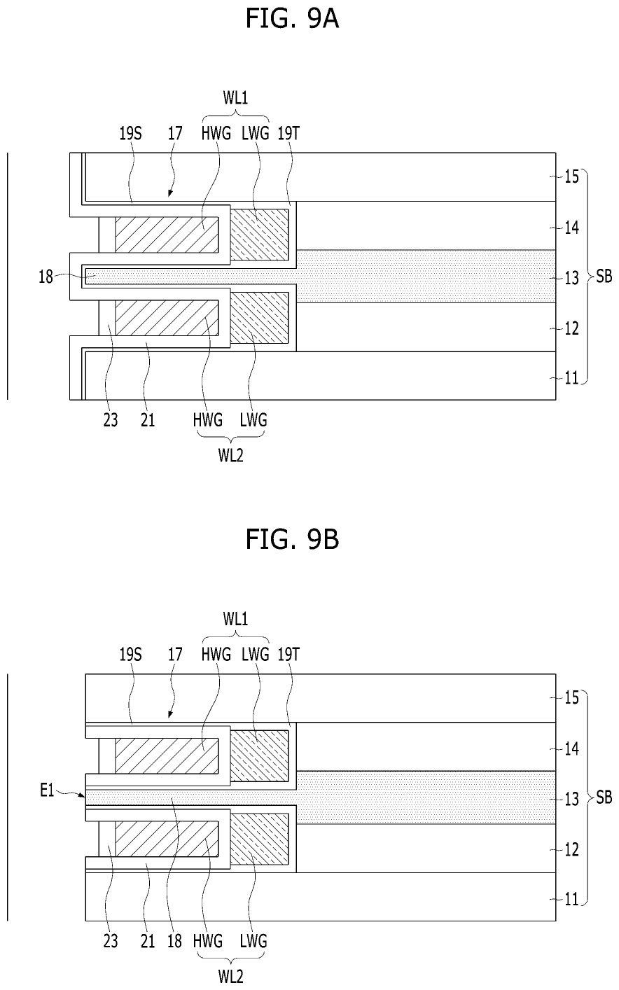

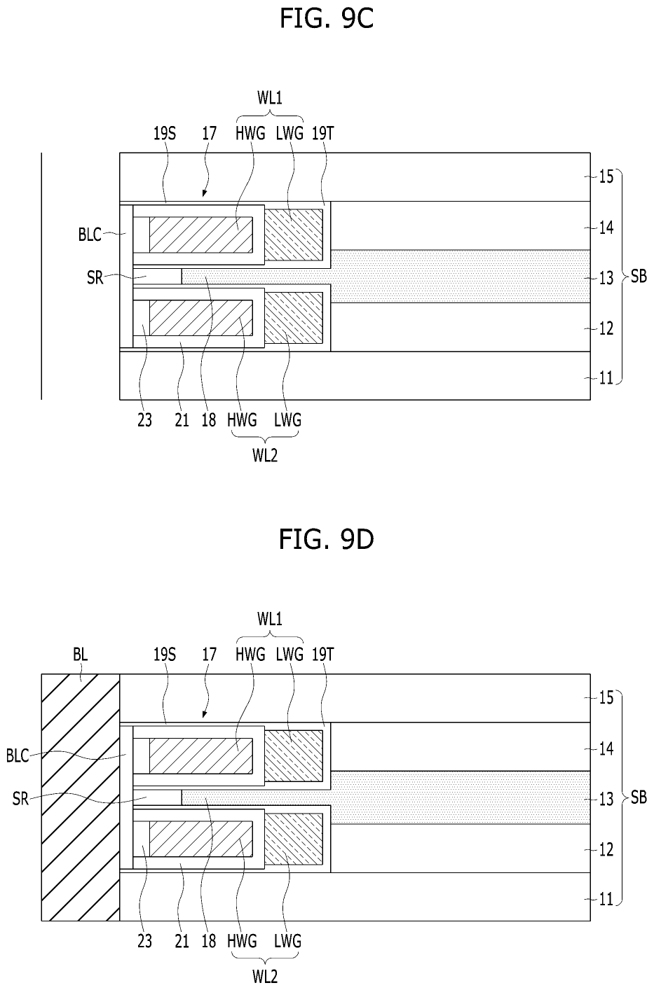

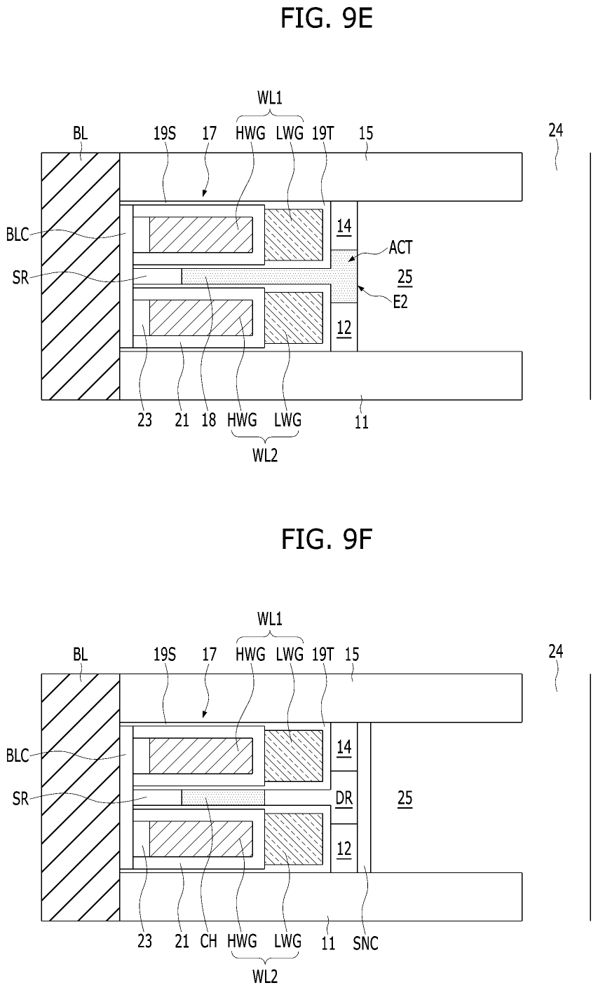

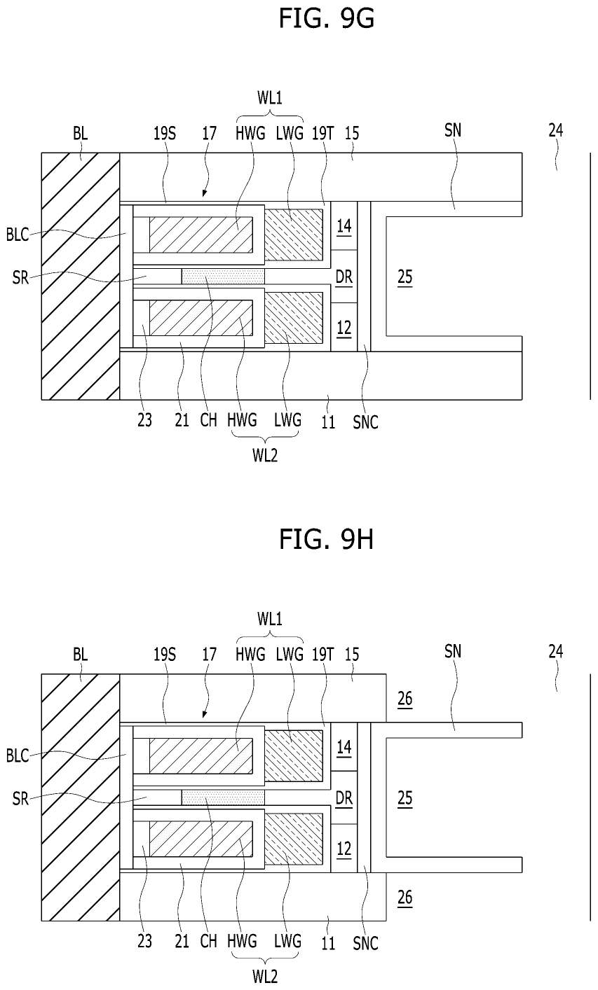

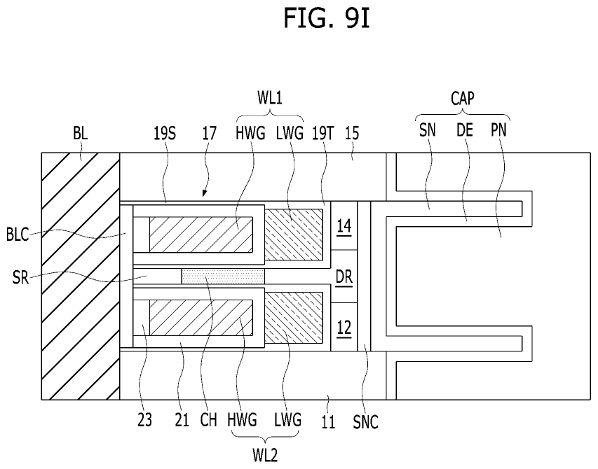

FIGS. 9A to 9I are cross-sectional views illustrating a method for forming a bit line and a capacitor in accordance with an embodiment of the present invention.

After the first and second word lines WL1 and WL2 are formed through a series of the processes illustrated in FIGS. 8A to 8I, as shown in FIG. 9A, protection layers 23 may be formed on the side of the high work function electrode HWG. The protection layers 23 may include silicon oxide or silicon nitride. The protection layers 23 may be recessed to fill a remaining space of the recesses 17 but not completely fill the recesses 17.

Referring to FIG. 9B, the second gate dielectric layer 19S and a portion of the capping layer 21 exposed by the protection layers 23 may be etched to expose a first end E1 of the thin-body 18.

Referring to FIG. 9C, a bit line contact node BLC coupled to the first end E1 of the thin body 18 may be formed. The bit line contact node BLC may include polysilicon which is doped with an impurity. The bit line contact node BLC may be coupled only to the first end E1 of the thin-body 18. Before the bit line contact node BLC is formed, the first end E1 of the thin-body 18, the capping layer 21, and the second gate dielectric layer 19S may be recessed. Accordingly, the first end E1 of the thin body 18, the capping layer 21, and the second gate dielectric layer 19S may be self-aligned to the sides of the protection layers 23.

While the bit line contact node BLC is formed or before the bit line contact node BLC is formed, a first source/drain region SR may be formed at the first end E1 of the thin-body 18. The first source/drain regions SR may be formed by forming polysilicon containing an impurity over the first opening 16 and then performing a subsequent heat treatment to diffuse the impurity from the polysilicon to the first end E1 of the first thin-body 18. Here, the polysilicon doped with the impurity may become a bit line contact node BLC. According to another embodiment of the present invention, the first source/drain region SR may be formed by doping an impurity and performing a heat treatment. Subsequently, the bit line contact node BLC may be formed.

Referring to FIG. 9D, a bit line BL in contact with the bit line contact node BLC may be formed. The bit line BL may fill the first opening 16. The bit line BL may include titanium nitride, tungsten, or a combination thereof. A bit line-side ohmic contact may be further formed between the bit line BL and the bit line contact node BLC. The bit line-side ohmic contact may include a metal silicide. For example, a metal silicide may be formed by sequentially performing metal layer deposition and annealing over the bit line contact node BLC, and the unreacted metal layer may be removed. The metal silicide may be formed by a reaction between the silicon of the bit line contact node BLC and the metal layer.

Referring to FIG. 9E, a second opening 24 may be formed by etching a second portion of the stack body SB. The second opening 24 may extend vertically. The second opening 24 may pass through the stack body SB.

Subsequently, the first and second sacrificial layers 12 and 14 and the remaining active layer 13 may be selectively recessed through the second opening 24. Accordingly, the capacitor opening 25 may be formed between the first inter-layer dielectric layer 11 and the second inter-layer dielectric layer 15. After the capacitor opening 25 is formed, the thin-body 18 and the active layer 13 may remain as represented by a reference symbol ‘ACT’. Hereinafter, the thin-body 18 and the active layer 13 will be simply referred to as the active layer ACT. One side of the active layer ACT may include the thin-body 18. The second end E2 of the active layer ACT may be exposed by the capacitor opening 25. According to another embodiment of the present invention, the thickness of the second end E2 of the active layer ACT may be the same as the thickness of the thin body 18.

Referring to FIG. 9F, a storage contact node SNC coupled to the second end E2 of the active layer ACT may be formed. The storage contact node SNC may include polysilicon which is doped with an impurity. The storage contact node SNC may be coupled only to the second end E2 of the active layer ACT.

A second source/drain region DR may be formed at the second end E2 of the active layer ACT while the storage contact node SNC is formed or before the storage contact node SNC is formed. The second source/drain regions DR may be formed by forming polysilicon containing an impurity over the second opening 24 and the capacitor opening 25 and then performing a subsequent heat treatment to diffuse the impurity from the polysilicon toward the second end E2 of the active layer ACT. Here, the polysilicon doped with the impurity may become a storage contact node SNC. According to another embodiment of the present invention, the second source/drain region DR may be formed by an impurity doping process and heat treatment. Subsequently, the storage contact node SNC may be formed.

Residual sacrificial layers 12 and 14 may be positioned between the storage contact node SNC and the first gate dielectric layer 19T.

A channel CH may be defined between the first source/drain region SR and the second source/drain region DR. A double gate dielectric layer of the second gate dielectric layer 19S and the capping layer 21 may be positioned between the channel CH and the high work function electrode HWG. A double gate dielectric layer of the second gate dielectric layer 19S and the capping layer 21 may be positioned between the first source/drain region SR and the high work function electrode HWG. A single gate dielectric layer of the first gate dielectric layer 19T may be positioned between the second source/drain region DR and the low work function electrode LWG and may contact the second source/drain region DR and the low work function electrode LWG.

Referring to FIG. 9G, the storage node SN in contact with the storage contact node SNC may be formed. The storage node SN may be formed by performing a conductive material deposition and an etch-back process. The storage node SN may include titanium nitride. The storage node SN may have a laterally oriented cylinder shape.

Referring to FIG. 9H, the outer wall of the storage node SN may be exposed by recessing the first and second inter-layer dielectric layers 11 and 15 (refer to a reference numeral 26).

Referring to FIG. 9I, a dielectric layer DE and a plate node PN may be sequentially formed over the storage node SN.

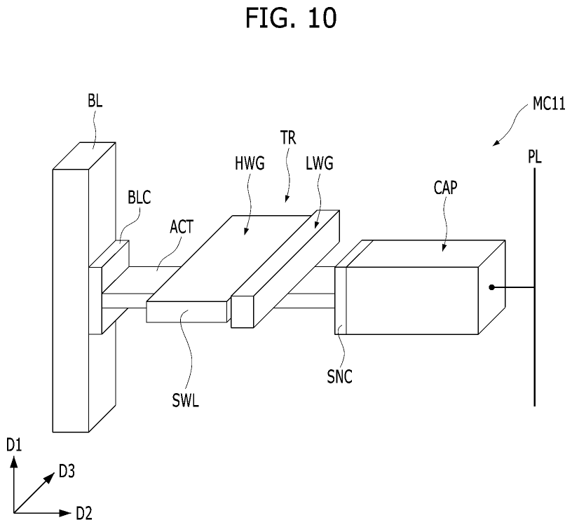

FIG. 10 is a schematic perspective view illustrating a memory cell MC11 in accordance with another embodiment of the present invention. The constituent elements of the memory cell MC11 shown in FIG. 10 except for the single word line SWL may be similar to those of the memory cell MC shown in FIGS. 1 and 2.

Referring to FIG. 10, the memory cell MC11 of the 3D semiconductor memory device may include a bit line BL, a transistor TR, and a capacitor CAP. The transistor TR may include an active layer ACT and a single word line SWL. The single word line SWL may be formed on the upper surface or the lower surface of the active layer ACT. The single word line SWL may include a low work function electrode LWG and a high work function electrode HWG. The low work function electrode LWG may be adjacent to the capacitor CAP, and the high work function electrode HWG may be adjacent to the bit line BL. The low work function electrode LWG and the high work function electrode HWG may not directly contact each other.

The memory cell MC11 may further include a gate dielectric layer and a capping layer. As for the gate dielectric layer and the capping layer of the memory cell MC11, FIG. 2 may be referred to. Referring back to FIGS. 2 and 10, the memory cell MC11 may include the capping layer DB between the low work function electrode LWG and the high work function electrode HWG, a first gate dielectric layer GD1 between the active layer ACT and the low work function electrode LWG, and a second gate dielectric layer GD2 positioned between the active layer ACT and the high work function electrode HWG and being thinner than the first gate dielectric layer GD1. The capping layer DB may extend to be positioned between the dielectric layer GD2 and the high work function electrode HWG.

According to another embodiment of the present invention, a plurality of the memory cells MC11 may form a memory cell array as illustrated in FIG. 3.

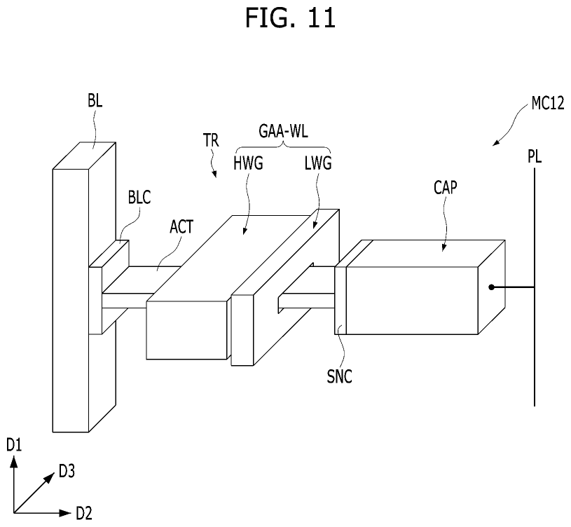

FIG. 11 is a schematic perspective view illustrating a memory cell MC12 in accordance with another embodiment of the present invention. Except for a gate all-around word lines GAA-WL, the constituent elements of the memory cell MC12 shown in FIG. 11 may be similar to those of the memory cell MC shown in FIGS. 1 and 2.

Referring to FIG. 11, the memory cell MC12 of the 3D semiconductor memory device may include a bit line BL, a transistor TR, and a capacitor CAP. The transistor TR may include an active layer ACT and gate all-around word lines GAA-WL. The gate all-around word lines GAA-WL may extend in the third direction D3 while surrounding a portion (i.e., a channel) of the active layer ACT. The active layer ACT may have a shape passing through the gate all-around word lines GAA-WL. The gate all-around word lines GAA-WL may include a low work function electrode LWG and a high work function electrode HWG. The low work function electrode LWG may be adjacent to the capacitor CAP, and the high work function electrode HWG may be adjacent to the bit line BL. The low work function electrode LWG and the high work function electrode HWG may not directly contact each other.

Although not illustrated, the memory cell MC12 may further include a gate dielectric layer and a capping layer. As for the gate dielectric layer of the memory cell MC12, FIG. 2 may be referred to. Referring back to FIGS. 2 and 11, the memory cell MC12 may include the capping layer DB between the low work function electrode LWG and the high work function electrode HWG, a first gate dielectric layer GD1 between the active layer ACT and the low work function electrode LWG, and a second gate dielectric layer GD2 positioned between the active layer ACT and the high work function electrode HWG and thinner than the first gate dielectric layer GD1. The capping layer DB may extend to be positioned between the dielectric layer GD2 and the high work function electrode HWG.

According to another embodiment of the present invention, a plurality of the memory cells MC12 may form a memory cell array as illustrated in FIG. 3.

According to an embodiment of the present invention, dopant loss may be suppressed by forming a capping layer between a low work function electrode and a high work function electrode, and the effect of a dual work function electrode using a flat-band shift may be increased.

According to an embodiment of the present invention, cell threshold voltage drop and electric field degradation may be reduced by forming a thick gate dielectric layer between a channel and a high work function electrode.

According to an embodiment of the present invention, as a capping layer and a thick gate insulating layer are formed, gate induced drain leakage (GIDL) caused by electric field improvement may be reduced and operating current (TOP) may be increased.

According to an embodiment of the present invention, as the word line has a dual work function electrode of a low work function electrode and a high work function electrode, it may be possible to realize low power consumption while securing the refresh characteristics of memory cells.

The effects desired to be obtained in the embodiment of the present invention are not limited to the effects mentioned above, and other effects not mentioned above may also be clearly understood by those of ordinary skill in the art to which the present invention pertains from the description below.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
an active layer including a channel which is spaced apart from a substrate and extending in a direction parallel to a surface of the substrate;
a gate dielectric layer formed over the active layer;
a word line oriented laterally over the gate dielectric layer to face the active layer, and including a low work function electrode and a high work function electrode which is parallel to the low work function electrode; and
a dielectric capping layer disposed between the high work function electrode and the low work function electrode.

2. The semiconductor device of claim 1, wherein the dielectric capping layer extends to cover an upper surface and a lower surface of the high work function electrode.

3. The semiconductor device of claim 1, wherein the dielectric capping layer includes silicon oxide.

4. The semiconductor device of claim 1, wherein the low work function electrode has a work function lower than a mid-gap work function of silicon, and the high work function electrode has a work function higher than the mid-gap work function of silicon.

5. The semiconductor device of claim 1, wherein the low work function electrode includes doped polysilicon which is doped with an N-type impurity.

6. The semiconductor device of claim 1, wherein the high work function electrode includes a metal-based material.

7. The semiconductor device of claim 1, wherein the high work function electrode includes titanium nitride, tungsten or a stack of titanium nitride and tungsten.

8. The semiconductor device of claim 1, wherein the active layer includes a semiconductor material or an oxide semiconductor material.

9. The semiconductor device of claim 1, wherein the active layer includes polysilicon, monocrystalline silicon, germanium, silicon-germanium or IGZO (Indium Gallium Zinc Oxide).

10. The semiconductor device of claim 1, wherein the gate dielectric layer includes:
a first gate dielectric layer disposed between the low work function electrode and the active layer; and
a second gate dielectric layer disposed between the high work function electrode and the active layer and thinner than the first gate dielectric layer,
wherein the dielectric capping layer extends to be disposed between the second gate dielectric layer and the high work function electrode.

11. The semiconductor device of claim 10, wherein the dielectric capping layer and the first and second gate dielectric layers include the same material.

12. The semiconductor device of claim 11, wherein each of the first gate dielectric layer and the second gate dielectric layer includes silicon oxide, silicon nitride, a metal oxide, a metal oxynitride, a metal silicate, a high-k material, a ferroelectric material, an anti-ferroelectric material, or a combination thereof.

13. The semiconductor device of claim 1, wherein the active layer further includes:
a first source/drain region disposed on one side of the channel; and
a second source/drain region disposed on another side of the channel,
wherein the first source/drain region is adjacent to the high work function electrode, and the second source/drain region is adjacent to the low work function electrode.

14. The semiconductor device of claim 13, further comprising:
a bit line coupled to the first source/drain region;
a capacitor including a storage node coupled to the second source/drain region;
a bit line contact node between the bit line and the first source/drain region; and
a storage contact node between the capacitor and the second source/drain region,
wherein the bit line is adjacent to the high work function electrode, and the storage node is adjacent to the low work function electrode.

15. The semiconductor device of claim 1, wherein the word line includes a double word line, a single word line, or a gate all-around word line.

16. A method for fabricating a semiconductor device, comprising:
forming an active layer which is vertically spaced apart from a substrate over an upper portion of the substrate;
forming a gate dielectric layer over the active layer;
forming a low work function electrode over the gate dielectric layer;
forming a dielectric capping layer on one side of the low work function electrode; and
forming a high work function electrode which is parallel to the low work function electrode over the dielectric capping layer.

17. The method of claim 16, wherein the forming of the dielectric capping layer includes:
depositing silicon oxide over one side of the low work function electrode; and
performing a heat treatment after the deposition of silicon oxide.

18. The method of claim 16, wherein the forming of the dielectric capping layer includes:
oxidizing the low work function electrode,
wherein, during the oxidizing of the low work function electrode, a portion of the gate dielectric layer is re-oxidized.

19. The method of claim 16, wherein the dielectric capping layer includes silicon oxide.

20. The method of claim 16, wherein the low work function electrode includes polysilicon doped with an N-type impurity, and
the high work function electrode includes a metal-based material.

21. The method of claim 16, wherein the high work function electrode includes titanium nitride, tungsten or a stack of titanium nitride and tungsten.

22. The method of claim 16, further comprising:
forming a first source/drain region at a first end of the active layer which is adjacent to the high work function electrode;
forming a bit line which is coupled to the first source/drain region and extends in a direction perpendicular to an upper surface of the substrate;
forming a second source/drain region at a second end of the active layer which is adjacent to the low work function electrode; and
forming a capacitor including a storage node which is coupled to the second source/drain region.

23. The method of claim 22, further comprising:
forming a bit line contact node between the first source/drain region and the bit line; and
forming a storage contact node between the second source/drain region and the storage node.

24. A method for fabricating a semiconductor device, comprising:
forming a stack body in which a first inter-layer dielectric layer, a first sacrificial layer, an active layer, a second sacrificial layer, and a second inter-layer dielectric layer are stacked in the mentioned order;
forming a first opening passing through the stack body;
forming recesses by recessing the first sacrificial layer and the second sacrificial layer through the first opening;
thinning the active layer which is exposed by the recesses;
forming a first gate dielectric layer over the thinned active layer;
forming a low work function electrode partially filling the recesses over the first gate dielectric layer;
forming a second gate dielectric layer by thinning a portion of the first gate dielectric layer which is exposed on one side of the low work function electrode;
forming a dielectric capping layer over the second gate dielectric layer and one side of the low work function electrode; and
forming a high work function electrode filling remaining portions of the recesses over the dielectric capping layer.

25. The method of claim 24, further comprising:
forming a first source/drain region at a first end of the active layer which is adjacent to the high work function electrode;
forming a bit line which is coupled to the first source/drain region and extends in a direction perpendicular to an upper surface of a substrate;
forming a second source/drain region at a second end of the active layer which is adjacent to the low work function electrode; and
forming a capacitor including a storage node which is coupled to the second source/drain region.
